(19) United States
(12) Patent Application Publication
(10) Pub. No.: US 2026/0190474 A1
(43) Pub. Date: Jul. 2, 2026

(54) TUB CAVITIES ENABLING INDEPENDENT PROCESSING OF CHANNELS AND SOURCE AND DRAIN EPIS

(71) Applicant: Intel Corporation, Santa Clara, CA (US)

(72) Inventors: Dan Lavric, Portland, OR (US); Glenn Glass, Portland, OR (US); Leonard Guler, Hillsboro, OR (US)

(73) Assignee: Intel Corporation, Santa Clara, CA (US)

(21) Appl. No.: 19/002,335

(22) Filed: Dec. 26, 2024

(51) Int. Cl. H10D 84/85; H10D 84/01

(52) U.S. Cl. CPC H10D 84/856; H10D 84/0167; H10D 84/017; H10D 84/0188; H10D 84/851

(57) ABSTRACT

Integrated circuit (IC) devices having gate-all-around transistors. An IC device may include a dielectric wall separating first and second source or drain bodies in first and second transistors, and the transistors may have first and second stacks of nanoribbons at different (e.g., offset) heights and coupled with the first and second source or drain bodies. The nanoribbons in the first and second nanoribbon stacks may have different thicknesses. The dielectric wall may enable independent processing of the first and second nanoribbon stacks.

### BACKGROUND

Conventional semiconductor patterning limitations are being approached as integrated circuit (IC) device, and the transistors within them, are continually scaled down. Typical patterning schemes face difficulties attempting to fabricate smaller and smaller semiconductor structures (such as source and drain bodies and the channels between them) with smaller and smaller separations between the structures. These difficulties are particularly acute when trying to manufacture multiple transistor variants of complementary types. For example, conventional patterning may struggle to form yet smaller nanoribbon channels of multiple thicknesses and materials (e.g., for complementary conductivity types), the cavity spacers between the channels, and the source and drain epi coupled to the channels, all with smaller pitches.

New techniques, structures, and materials are needed to improve IC scaling and performance, including processing schemes and tools to form source and drain epi at very fine pitches and channels of multiple thicknesses and materials.

### BRIEF DESCRIPTION OF THE DRAWINGS

The material described herein is illustrated by way of example and not by way of limitation in the accompanying figures. For simplicity and clarity of illustration, elements illustrated in the figures are not necessarily drawn to scale. For example, the dimensions of some elements may be exaggerated relative to other elements for clarity. Further, where considered appropriate, reference labels have been repeated among the figures to indicate corresponding or analogous elements, e.g., with the same or similar functionality. The disclosure will be described with additional specificity and detail through use of the accompanying drawings:

FIG. 1 illustrates cross-sectional plan and profile views of an integrated circuit (IC) device having a dielectric wall separating adjacent source or drain bodies and transistor structures, in accordance with some embodiments;

FIG. 2 illustrates cross-sectional profile views of an IC device with a dielectric wall between nanoribbons of different materials and heights in transistor structures, in accordance with some embodiments;

FIG. 3 illustrates cross-sectional profile views of an IC device having multiple stacks of nanoribbons with different thicknesses, in accordance with some embodiments;

FIG. 4 is a flow chart of methods for forming a dielectric wall between two nanoribbon stacks and processing the two nanoribbon stacks independently, in accordance with some embodiments;

FIGS. 5A, 5B, 5C, 5D, 5E, 5F, 5G, 5H, 5I, and 5J illustrate cross-sectional profile views of an IC device having stacks of nanoribbons with different characteristics (such as heights and thicknesses), at various stages of manufacture, in accordance with some embodiments;

FIG. 6 illustrates a diagram of an example data server machine employing an IC device having source and drain bodies coupled with offset nanoribbons and separated by dielectric walls; and

FIG. 7 is a block diagram of an example computing device, in accordance with some embodiments.

### DETAILED DESCRIPTION

In the following detailed description, reference is made to the accompanying drawings that show, by way of illustration, specific embodiments in which the claimed subject matter may be practiced. These embodiments are described in sufficient detail to enable those skilled in the art to practice the subject matter. The various embodiments, although different, are not necessarily mutually exclusive. For example, a particular feature, structure, or characteristic described herein, in connection with one embodiment, may be implemented within other embodiments without departing from the spirit and scope of the claimed subject matter.

References within this specification to “one embodiment” or “an embodiment” mean that a particular feature, structure, or characteristic described in connection with the embodiment is included in at least one implementation encompassed within the present description. Therefore, the use of the phrase “one embodiment” or “in an embodiment” does not necessarily refer to the same embodiment. In addition, the location or arrangement of individual elements within each disclosed embodiment may be modified without departing from the spirit and scope of the claimed subject matter. The following detailed description is, therefore, not to be taken in a limiting sense, and the scope of the subject matter is defined only by the appended claims, appropriately interpreted, along with the full range of equivalents to which the appended claims are entitled.

The terms “over,” “to,” “between,” and “on” as used herein may refer to a relative position of one layer with respect to other layers. One layer “over” or “on” another layer or bonded “to” another layer may be directly in contact with the other layer or may have one or more intervening layers. One layer “between” layers may be directly in contact with the layers or may have one or more intervening layers.

The terms “coupled” and “connected,” along with their derivatives, may be used herein to describe structural relationships between components. These terms are not intended as synonyms for each other. Rather, in particular embodiments, “connected” may be used to indicate that two or more elements are in direct physical or electrical contact with each other. “Coupled” may be used to indicate that two or more elements are in either direct or indirect (with other intervening elements between them) physical or electrical contact with each other, and/or that the two or more elements co-operate or interact with each other (e.g., as in a cause-and-effect relationship, an electrical relationship, a functional relationship, etc.).

The term “circuit” or “module” may refer to one or more passive and/or active components that are arranged to cooperate with one another to provide a desired function. The term “signal” may refer to at least one current signal, voltage signal, magnetic signal, or data/clock signal. The meaning of “a,” “an,” and “the” include plural references. The meaning of “in” includes “in” and “on.”

The vertical orientation is in the z-direction and recitations of “top,” “bottom,” “above,” and “below” refer to relative positions in the z-dimension with the usual meaning. However, embodiments are not necessarily limited to the orientations or configurations illustrated in the figure.

The terms “substantially,” “close,” “approximately,” “near,” and “about,” generally refer to being within +/—10% of a target value (unless specifically specified). Unless otherwise specified in the specific context of use, the term “predominantly” means more than 50%, or more than half. For example, a composition that is predominantly a first constituent means more than half of the composition is the first constituent. The term “primarily” means the most, or greatest, part. For example, a composition that is primarily a first constituent means the composition has more of the first constituent than any other constituent. A composition that is primarily first and second constituents means the composition has more of the first and second constituents than any other constituent.

Unless otherwise specified the use of the ordinal adjectives “first,” “second,” and “third,” etc., to describe a common object, merely indicate that different instances of like objects to which are being referred and are not intended to imply that the objects so described must be in a given sequence, either temporally, spatially, in ranking or in any other manner.

For the purposes of the present disclosure, phrases “A and/or B” and “A or B” mean (A), (B), or (A and B). For the purposes of the present disclosure, the phrase “A, B, and/or C” means (A), (B), (C), (A and B), (A and C), (B and C), or (A, B and C).

Views labeled “cross-sectional,” “profile,” and “plan” correspond to orthogonal planes within a cartesian coordinate system. Thus, cross-sectional and profile views are taken in the x-z and y-z planes, and plan views are taken in the x-y plane. Typically, profile views in the x-z plane are cross-sectional views. Where appropriate, drawings are labeled with axes to indicate the orientation of the figure.

Structures, materials, and techniques are disclosed to improve the performance and scaling integrated circuit (IC) devices having gate-all-around (GAA) transistors.

Dielectric walls may be employed to separate adjacent nanoribbon stacks into individual processing compartments (“tubs”), thereby enabling independent fabrication of channels and source and drain bodies in adjacent GAA field-effect transistors (FETs). Instead of every nanoribbon stack in a shared gate or source-drain trench undergoing the same processing, each nanoribbon stack may have its own gate tub between source-drain tubs and receive specifically tailored processing. The dielectric walls may be formed by making etches between the nanoribbon stacks and by filling the etched openings with dielectric, forming many isolations between many nanoribbon stacks. Openings may be patterned through a hardmask layer deposited over the walls and nanoribbon stacks, and sacrificial (e.g., dummy) material may be removed through the openings, evacuating selected tubs between the dielectric walls.

The mask openings may be made to evacuate groups of tubs selected for a particular processing operation. For example, the source-drain tubs for many nanoribbon stacks to receive a certain spacer variant may be evacuated together and then be processed concurrently. The hardmask layer may be removed following the completion of the particular processing operation, a new hardmask layer may be deposited, and new openings may be patterned to evacuate a new group of tubs for a next processing operation (e.g., the formation of a second spacer variant). The dielectric walls may be retained after structure (e.g., source and drain) formation as electrical isolation between adjacent structures.

The tailored processing enabled by the source-drain and gate tubs may be used to provide multiple transistor variants, for example, having different channel materials and thicknesses (and so different threshold voltages V_{T}). An IC device may have multiple channel variants for each of multiple complementary conductivity types. In many embodiments, adjacent transistors have different channel thicknesses (and so different threshold voltages V_{T} for a same conductivity type). In many embodiments, adjacent transistors have different channel heights. In many embodiments, adjacent transistors have different channel materials (e.g., for complementary conductivity types). In many embodiments, adjacent transistors have different source-drain materials (e.g., for complementary conductivity types). In many embodiments, adjacent transistors of complementary conductivity types have different source-drain heights (and so reduced parasitic capacitances). In many embodiments, adjacent transistors have different gate cavity spacer materials. In many embodiments, adjacent source-drain epis are grown to the sidewalls of the dielectric walls between them, and the dielectric walls provide fine-pitch isolation between adjacent transistors.

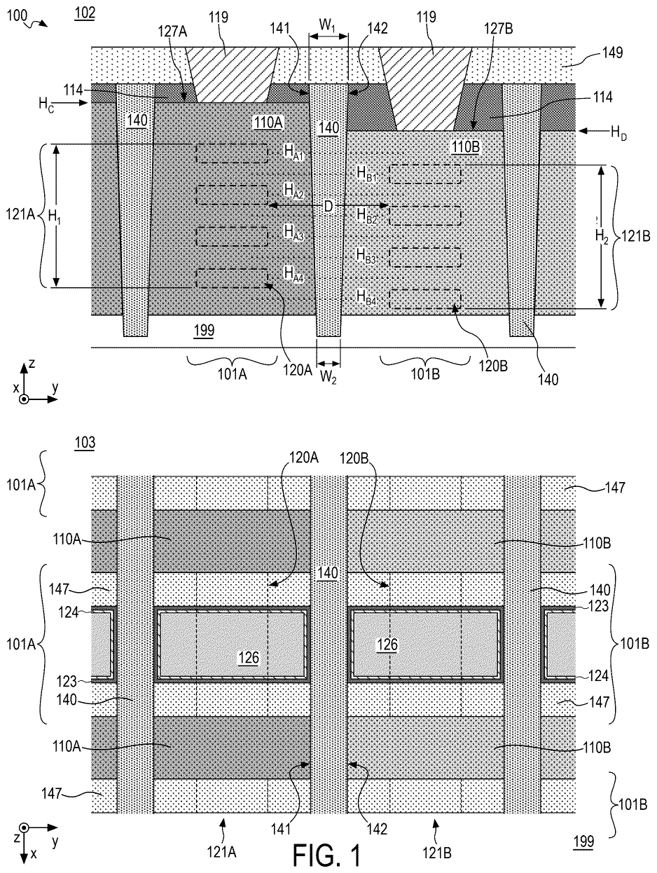

FIG. 1 illustrates cross-sectional plan and profile views of an IC device 100 having a dielectric wall 140 separating adjacent source or drain bodies 110A, 110B and transistor structures 101A, 101B, in accordance with some embodiments. Transistor structures 101A, 101B may have parts (such as nanoribbons 120 and source or drain bodies 110A, 110B) of different materials and dimensions. Profile view 102 has a cross-sectional y-z viewing plane through source or drain bodies 110A, 110B of transistor structures 101A, 101B. Plan view 103 has a cross-sectional x-y viewing plane through source or drain bodies 110A, 110B and gate electrodes 126 of transistor structures 101A, 101B (e.g., just under an upper surface 127B of source or drain body 110B, below dielectric layer 114). Nanoribbons 120 (e.g., nanoribbons 120A, 120B) not in the viewing plane are shown (e.g., for reference) with dashed lines.

IC device 100 includes transistor structures 101A, 101B. A first source or drain body 110A is coupled with a stack 121A of first nanoribbons 120A in a first transistor structure 101A. A second source or drain body 110B is coupled with a stack 121B of second nanoribbons 120B in a second transistor structure 101B. In the exemplary embodiments of FIG. 1, etc., stacks 121A, 121B each have four nanoribbons 120A, 120B, but stacks 121A, 121B may have any suitable number of nanoribbons 120A, 120B. In some embodiments, stacks 121A, 121B each have three nanoribbons 120A or 120B. In other embodiments, stacks 121A, 121B each have five nanoribbons 120A or 120B.

As shown in view 103, source or drain bodies 110 are electrically and physically coupled to opposite ends of channel-region nanoribbons 120. In many embodiments, transistor structures 101 are each physically symmetrical about nanoribbons 120 (e.g., channel regions) and gate electrodes 126, and identifiers “drain” and “source” for bodies 110 may be reversed interchangeably in many contexts. However, the classification of source or drain bodies 110 may be by the electrical relationships of transistor structures 101 and bodies 110 to other components in a given circuit (e.g., and the consequent direction of current flow through structures 101 and bodies 110). Some source or drain bodies 110 may simultaneously be a source body 110 in one transistor structure 101 and a drain body 110 in another transistor structure 101.

Source or drain bodies 110 may be impurity doped regions, e.g., regions of semiconductor material doped with one or more electrically active impurities and having increased charge-carrier availabilities and associated conductivities. Bodies 110 in different transistor structures 101 may be doped with an opposite type (e.g., n- or p-type) or of similar type. Source or drain bodies 110 may include a predominant semiconductor material, and one or more n-dopants (such as phosphorus, arsenic, or antimony) or p-type impurities (such as boron or aluminum). Other dopant materials may be used. Any suitable means of formation may be used. Bodies 110 may be epitaxially grown semiconductor regions, for example, of a Group IV semiconductor material (e.g., Si, Ge, SiGe, GeSn alloy). Other semiconductor materials may be employed. Bodies 110 may be substantially crystalline. Source or drain bodies 110 may be polycrystalline or substantially monocrystalline, e.g., having long-range order at least adjacent ends of nanoribbons 120 and merging or joining into a unitary body with few grain boundaries.

Source or drain bodies 110A, 110B may be of different materials, for example, to improve performance in complementary transistor structures 101A, 101B. In many embodiments, structure 101A is an n-type transistor structure 101A, and body 110A is predominantly silicon. In many embodiments, structure 101B is a p-type transistor structure 101B, and body 110B includes silicon and germanium.

Source or drain bodies 110A, 110B need not be the same size. As in the exemplary embodiment shown in view 102, one of bodies 110A, 110B may have a reduced height H_{C} or H_{D}, e.g., and correspondingly reduced parasitic capacitances. In some embodiments, a first (vertical position or) height H_{C} of a first upper surface 127A of the first source or drain body 110A is greater than a second (vertical position or) height H_{D} of a second upper surface 127B of the second source or drain body 110B. The difference in heights H_{C}, H_{D} may be enabled by a dielectric wall 140 between bodies 110A, 110B.

As shown in view 102, dielectric wall 140 is between source or drain bodies 110A, 110B. Wall 140 includes opposing first and second sidewalls 141, 142, and dielectric wall 140 is in direct contact with bodies 110A, 110B at sidewalls 141, 142. Walls 140 (e.g., sidewalls 141, 142) extend beyond and below the bottoms (e.g., lower surfaces) of bodies 110A, 110B, for example, into substrate 199. As shown in view 103, dielectric wall 140 is between stacks 121A, 121B of first and second nanoribbons 120A, 120B, gate electrodes 126, and source or drain bodies 110A, 110B. Dielectric wall 140 extends through spacers 147. Gate dielectric layer 123 is on electrodes 126 (e.g., in a gate stack or structure with gate electrode 126) and on dielectric wall 140 (e.g., at sidewalls 141, 142) and spacers 147. Dielectric wall 140 is an isolation structure, e.g., providing electrical isolation between electrodes 126 and between bodies 110A, 110B. Other gate electrodes 126, etc., not shown, are in other transistor structures 101 just beyond edges of view 103 (e.g., in the x-directions).

Wall 140 includes a width W₁ (or width W₂) of dielectric wall 140 separating sidewalls 141, 142. Dielectric wall 140 (e.g., sidewalls 141, 142) may be nearly vertical. In many embodiments, dielectric wall 140 has widths W₁, W₂ differing only slightly (e.g., in a tapering profile that narrows slightly upwards or downwards). For example, widths W₁, W₂ may be within 1 nm. Width W₁ is defined as the width of wall 140 at a top of wall 140. Width W₂ is defined as the width of wall 140 at a bottom of bodies 110, e.g., where wall 140 meets substrate 199 at a bottom of body 110. Dielectric wall 140 (and so width W₁ or W₂) separates bodies 110A, 110B in transistor structures 101A, 101B (respectively). Wall 140 is between and in contact with source or drain bodies 110A, 110B, e.g., at sidewalls 141, 142. Multiple dielectric walls 140 are shown in views 102, 103. Each wall 140 is between a pair of source or drain bodies 110, and each body 110 is between a pair of dielectric walls 140. Each wall 140 has sidewalls 141, 142 in contact with a different source or drain body 110, and each body 110 is between and in contact with dielectric sidewalls 141, 142 of different dielectric walls 140.

In many embodiments, dielectric wall 140 has a minimum width W₂ (or width W₁, etc.) of 12 nm or less between source or drain bodies 110A, 110B, which may enable sufficiently tight packing of transistor structures 101A, 101B and a consequent conservation of layout area. In some embodiments, dielectric wall 140 has a minimum width W₂ (or width W₁, etc.) of 10 nm or less between bodies 110A, 110B, which may enable superior packing of transistor structures 101A, 101B and conservation of layout area. Such (small widths W₁, W₂ and) tight laying out of structures 101 may be enabled by a fine, high aspect ratio etch (e.g., when forming wall 140).

The tight packing of stacks 121 and transistor structures 101 may be characterized by a small distance D separating the first and second stacks 121A, 121B of nanoribbons 120. In many embodiments, distance D is less than three times a maximum width W₁ of wall 140, e.g., with wall 140 centered between stacks 121, about a width W₁ (or less) from either stack.

Isolation wall 140 includes any suitable material(s), for example, a dielectric material. Wall 140 advantageously includes a low-k (low-permittivity) dielectric material. Wall 140 advantageously has an etch selectivity with other adjacent structures. In many embodiments, wall 140 includes silicon and nitrogen (e.g., in a nitride of silicon). In some embodiments, wall 140 includes silicon and oxygen (e.g., in an oxide of silicon). In some embodiments, wall 140 includes carbon and/or nitrogen, for example, in addition to silicon and oxygen.

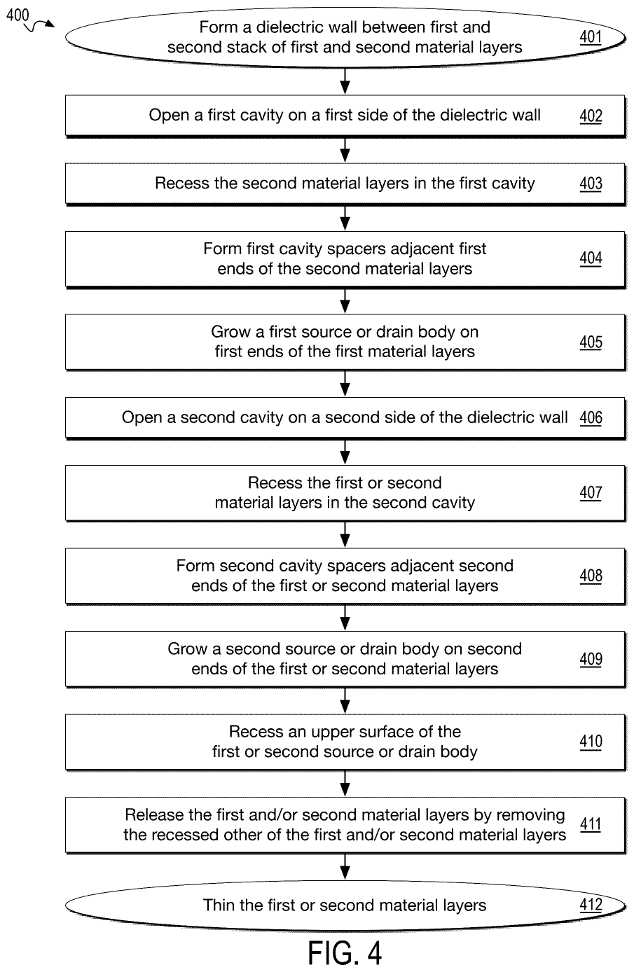

Isolation wall 140 may enable the independent processing of source or drain bodies 110A, 110B in structures 101A, 101B (e.g., as described at least at FIG. 4 and methods 400), which allows for bodies 110A, 110B of different sizes (e.g., heights H_{C}, H_{D}) and compositions. Wall 140 may also enable the independent processing of stacks 121A, 121B of nanoribbons 120A, 120B in structures 101A, 101B (e.g., as described at least at FIG. 4 and methods 400), which allows for transistor structures 101A, 101B with nanoribbons 120A, 120B of different heights, thicknesses, compositions, etc.

For example, nanoribbons 120A in structure 101A may have heights H_{A} offset from heights H_{B} of nanoribbons 120B in structure 101B. As in the exemplary embodiment shown in view 102, first heights H_{A1}-H_{A4} of first nanoribbons 120A may be offset and interleaved with second heights H_{B1}-H_{B4} of second nanoribbons 120B. Each adjacent pair of second nanoribbons 120B includes upper and lower nanoribbons 120B, with the upper nanoribbon 120B having a first axis (e.g., centerline) at a first height H_{BX} above a second axis at a second height H_{A(X+1)} of an adjacent first nanoribbon 120A and the lower second nanoribbon 120B with a third axis at a third height H_{B(X+1)} below the second axis of the adjacent nanoribbon 120A. Each adjacent pair of first nanoribbons 120A includes upper and lower nanoribbons 120A, with the upper nanoribbon 120A having a first axis at a first height H_{AX} above a second axis at a second height H_{BX} of an adjacent second nanoribbon 120B and the lower nanoribbon 120A with a third axis at a third height H_{A(X+1)} below the second axis of the adjacent first nanoribbon 120A.

In the exemplary embodiment of view 102, nanoribbons 120A, 120B are evenly spaced in alternating fashion, with each of first nanoribbons 120A a constant interval above (e.g., at a higher height H_{A} than) corresponding second nanoribbons 120B (e.g., at a lower height H_{B}), which are the constant interval above the next nanoribbon 120A. Stacks 121A, 121B have equal and constant pitches; a vertical pitch between nanoribbons 120A in stack 121A (the identical differences between heights H_{A1}, H_{A2}; between heights H_{A2}, H_{A3}; and between heights H_{A3}, H_{A4}) is equal to a vertical pitch between nanoribbons 120B in stack 121B (the identical differences between heights H_{B1}, H_{B2}; between heights H_{B2}, H_{B3}; and between heights H_{B3}, H_{B4}). In the context of pitches, heights (whether vertical positions or spans), thicknesses, etc., of nanoribbons 120, dimensions (e.g., heights, etc.) are considered approximately equal if the dimensions are within 1 nm. Nanoribbons 120B (except for the lowest nanoribbon 120B) are vertically centered between nearest-neighbor nanoribbons 120A (e.g., a half-pitch above and below the nearest-neighbor nanoribbons 120A). Nanoribbons 120A (except for the highest nanoribbon 120A) are vertically centered between nearest-neighbor nanoribbons 120B (e.g., a half-pitch above and below the nearest-neighbor nanoribbons 120B).

Heights H_{A1}-H_{A4}, H_{B1}-H_{B4} are vertical positions of nanoribbons 120A, 120B referenced to axes or centerlines of nanoribbons 120A, 120B, but nanoribbons 120A, 120B may be otherwise referenced (e.g., to upper or lower surfaces of nanoribbons 120A, 120B) with the same resultant interleaving (e.g., ordering) of heights H_{A1}-H_{A4}, H_{B1}-H_{B4}. In some embodiments, the lower surface of each of nanoribbons 120A, 120B in stacks 121A, 121B is coplanar with an upper surface of the lower nearest-neighbor nanoribbon 120B, 120A in the other stack 121B, 121A. For example, nanoribbons 120A, 120B in stacks 121A, 121B may come from a same stack of alternating layers (e.g., with each type of nanoribbon 120A or 120B having a different layer composition), and nearest-neighbor nanoribbons 120A, 120B in opposite stacks 121A, 121B may come from layers that had previously been adjoining. In some other embodiments (e.g., with thinner nanoribbons 120A and/or 120B), the lower surface of each of nanoribbons 120A, 120B in stacks 121A, 121B is above an upper surface of the lower nearest-neighbor nanoribbon 120B, 120A in the other stack 121B, 121A.

In many embodiments, vertical spans or heights H₁, H₂ of stacks 121A, 121B are equal. In the exemplary embodiment of view 102, vertical spans or heights H₁, H₂ span from a lower surface of a lowest nanoribbon 120A, 120B to an upper surface of a highest nanoribbon 120A, 120B in stacks 121A, 121B, respectively.

As shown in view 103, nanoribbons 120 extend through gate electrodes 126, which may control the conduction through nanoribbons 120 (e.g., of transistor structures 101). Gate electrodes 126 in transistor structures 101A, 101B and over stacks 121A, 121B may be the same or different, for example, having metal layers of different quantity and quality. For example, electrodes 126 in structures 101A, 101B may include different workfunction metals, such as liner layers 124. Gate electrodes 126 may be part of gate structures that include gate dielectric layers 123 (e.g., high-k gate dielectric layers 123), which may be of different quantity and quality in transistor structures 101A, 101B. More or different gate dielectric layers 123 may be on electrodes 126 in structures 101A, 101B. As in the exemplary embodiment illustrated in FIG. 1, only dielectric layers 123 may separate gate electrodes 126 (e.g., metal layers 124) from walls 140. Metal layers 124 are on dielectric layers 123 on dielectric walls 140 and spacers 147.

Spacers 147 (as illustrated at view 103) are isolation structures, e.g., of insulator material (such as a low-k dielectric), adjacent gate electrodes 126 and source or drain bodies 110. Spacers 147 provide isolation (e.g., electrical isolation) between electrodes 126 and bodies 110.

Source and drain contact structures 119 (e.g., via structures 119) are metallization structures 119 that couple (e.g., electrically couple) bodies 110, for example, with an interconnect network (not shown) above transistor structures 101. Contact structures 119 may include any suitable material(s), including non-metals. For example, contact structures 119 may include an interface (e.g., silicide) layer on bodies 110. Structures 119 may include multiple layers of metals, for example, a liner (e.g., barrier or seed) layer around a fill layer. Contact structures 119 are through a dielectric layer 149 over transistor structures 101A, 101B. Dielectric layer 149 may be of any suitable material, such as a low-k dielectric material.

Substrate 199 may include any suitable material or materials. Substrate 199 may be an IC substrate, such as an IC die or wafer. In some examples, the substrate may include monocrystalline silicon (including silicon on insulator (SOI)), polycrystalline silicon, germanium, silicon germanium, a III-V alloy material (e.g., gallium arsenide), a silicon carbide (e.g., SiC), a sapphire (e.g., Al₂O₃), or any combination thereof. Substrate 199 may also include semiconductor materials, metals, dielectrics, dopants, and other materials commonly found in semiconductor substrates. Substrate 199 may refer specifically to a base material (for example, a thick base or layer of semiconductor material) that other materials (such as metals and dielectrics) are built up on. In some contexts, substrate 199 may refer to a base material layer and any build-up layers, etc., over the base. Transistor structures 101 may be over a dielectric layer over other (e.g., semiconductor) materials.

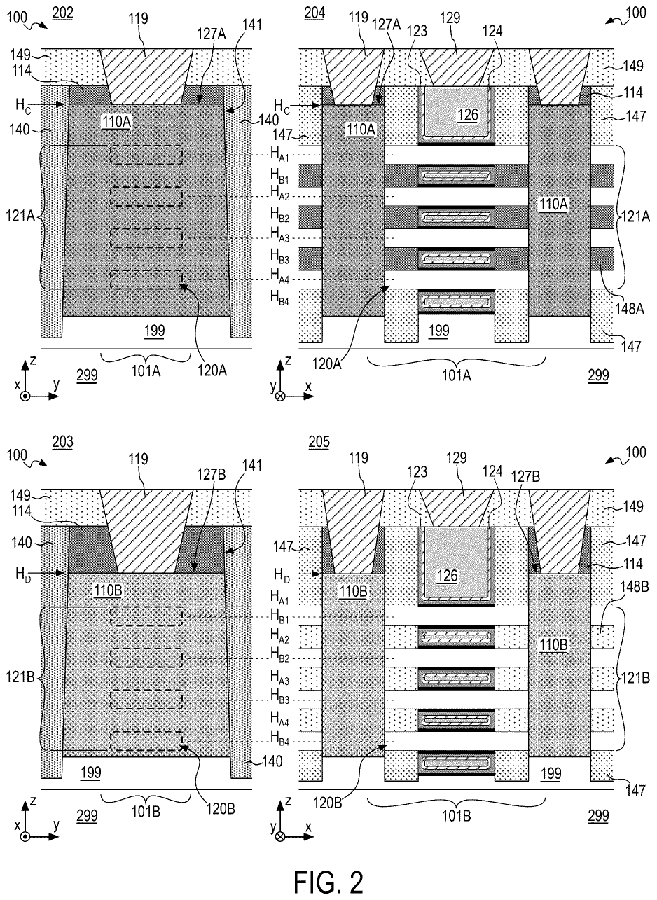

FIG. 2 illustrates cross-sectional profile views of an IC device 100 with dielectric wall 140 between nanoribbons 120A, 120B of different materials and heights in transistor structures 101A, 101B, in accordance with some embodiments. Views 202, 204 show source or drain bodies 110A and nanoribbons 120A in transistor structure 101A. Views 203, 205 illustrate source or drain bodies 110B and nanoribbons 120B in transistor structure 101B. Dielectric wall 140 (not shown in views 204, 205 of FIG. 2) is between stacks 121A, 121B of nanoribbons 120A, 120B in transistor structures 101A, 101B.

Views 202, 204 are y-z and x-z cross-sectional profile views of source or drain bodies 110A and nanoribbons 120A in transistor structure 101A. View 202 is a portion of view 102 of FIG. 1 (e.g., of transistor structure 101A) and provides a reference for x-z cross-sectional profile view 204 through nanoribbons 120A. Views 202, 204 are vertically aligned, for example, with heights H_{A1}-H_{A4} of nanoribbons 120A aligned between views 202, 204. As in FIG. 1, heights H_{A1}-H_{A4} of nanoribbons 120A are offset from (and interleaved with) heights H_{B1}-H_{B4} of nanoribbons 120B. Spacers 147 are over nanoribbons 120A. Spacers 148A are between and under nanoribbons 120A.

Views 203, 205 are y-z and x-z cross-sectional profile views of source or drain bodies 110B and nanoribbons 120B in transistor structure 101B. View 203 is a portion of view 102 of FIG. 1 (e.g., of transistor structure 101B) and provides a reference for x-z cross-sectional profile view 205 through nanoribbons 120B. Views 203, 205 are vertically aligned, for example, with heights H_{B1}-H_{B4} of nanoribbons 120B aligned between views 203, 205. As in FIG. 1, heights H_{A1}-H_{A4} of nanoribbons 120A are offset from (and interleaved with) heights H_{B1}-H_{B4} of nanoribbons 120B. Spacers 147 are over nanoribbons 120B. Spacers 148B are between and under nanoribbons 120B.

As described (at least) at FIG. 1, dielectric wall 140 may enable the independent processing of stacks 121A, 121B of nanoribbons 120A, 120B in transistor structures 101A, 101B, which allows for structures 101A, 101B with nanoribbons 120A, 120B of different heights, thicknesses, compositions, etc. For example, nanoribbons 120 may have any suitable width (e.g., in the y-dimension) and may be, e.g., nanowire nanoribbons 120 or nanosheet nanoribbons 120. Deploying nanoribbons 120A, 120B of different material compositions may improve performance by allowing the employment of optimal materials for different transistor structures 101. In many embodiments, transistor structures 101A, 101B are of complementary conductivity types (e.g., n-and p-types). In many embodiments, structure 101A is an n-type transistor structure 101A, and first nanoribbons 120A are predominantly silicon. In some such embodiments, source or drain body 110A is predominantly silicon. In many embodiments, structure 101B is a p-type transistor structure 101B, and second nanoribbons 120B include silicon and germanium. In some such embodiments, source or drain body 110B includes silicon and germanium. Nanoribbons 120 provide channel regions for transistor structures 101 and may be of any (e.g., semiconducting) material(s) suitable for use as channel regions. Nanoribbons 120A in stack 121A may be the same or different than nanoribbons 120B in stack 121B.

First and second gate electrodes 126 in transistor structures 101A, 101B, respectively, may be different or substantially similar. Gate electrodes 126 may include metal layers (including layers 124), which may be different or substantially similar in transistor structures 101A, 101B. Gate electrodes 126 may be part of gate structures that also include dielectric layers 123, which are on electrodes 126 and on spacers 147, 148A, 148B. Gate dielectric layers 123 insulate channel regions of nanoribbons 120A, 120B from electrodes 126 and may be different or substantially similar in transistor structures 101A, 101B. (Nanoribbons 120 may also have other dielectric layers, such as passivation layers on nanoribbons 120A, 120B, insulating channel regions of nanoribbons 120A, 120B from electrodes 126.)

Spacers 147, 148A, 148B are isolation structures, e.g., of insulator material (such as a low-k dielectric material), adjacent gate electrodes 126. Spacers 148 provide isolation between electrodes 126 and bodies 110. Spacers 147 provide isolation between electrodes 126 and bodies 110 and contact structures 119 over bodies 110. Dielectric wall 140 may enable the independent processing of spacers 148A, 148B adjacent stacks 121A, 121B and so the use of different (e.g., optimized) materials in spacers 148A, 148B. In many embodiments, the dielectric material(s) of spacers 148A, 148B have mutual etch selectivities.

As shown in view 204, first transistor structure 101A includes first gate electrode 126 with first cavity spacer 148A between first gate electrode 126 and source or drain body 110A and between adjacent nanoribbons 120A in structure 101A. As shown in view 205, second transistor structure 101B includes second gate electrode 126 with second cavity spacer 148B between second gate electrode 126 and source or drain body 110B and between adjacent nanoribbons 120B in structure 101B. In many embodiments, first and second cavity spacers 148A, 148B have different compositions. In some embodiments, spacers 148A, 148B have etch selectivities. In some embodiments, nanoribbons 120A, 120B are of different compositions, and spacers 148A, 148B are of different compositions, e.g., optimized for use as cavity spacers 148 adjacent nanoribbons 120A, 120B of different compositions. For example, spacers 148A, 148B may each be compositionally different dielectric materials that deposit selectively on the different sacrificial materials between nanoribbons 120A, 120B, respectively. In some embodiments, nanoribbons 120A are predominantly silicon, and spacers 148A are of a dielectric material that deposits on SiGe (e.g., sacrificial material) selective to Si, SiOC, SiOCN, SiO surfaces. In some embodiments, nanoribbons 120B include silicon and germanium, and spacers 148B are of a dielectric material that deposits on Si (e.g., sacrificial material) selective to SiGe surfaces.

Gate via structures 129 are metallization structures that couple (e.g., electrically couple) gate electrodes 126, for example, with an interconnect network (not shown) above transistor structures 101. Via structures 129 may include any suitable material(s), including non-metals. Via structures 129 may include multiple layers of metals, for example, a liner (e.g., barrier or seed) layer around a fill layer. Gate via structures 129 are through dielectric layer 149 over transistor structures 101A, 101B.

IC device 100 may include or be coupled to a substrate or other host component 299. Host component 299 may be a package substrate, an interposer, an IC die, etc. For example, substrate 199 may be an IC die that includes transistor structures 101, substrate 199 may be coupled (e.g., soldered or otherwise bonded) to host component 299, and device 100 and transistor structures 101 may be coupled to a power supply (not shown) through host component 299.

Host component 299 is a planar platform and may include dielectric and metallization structures. Host component 299 mechanically supports and electrically couples one or more IC devices 100. At least one side of host component 299 includes substrate interconnect interfaces for bonding to one or more IC devices 100. IC device 100 may be direct bonded, e.g., hybrid bonded, to host component 299 or otherwise bonded, e.g., by optional solder bumps. The opposite side of host component 299 may include similar interfaces, e.g., copper pads for socketing and/or solder bumps for bonding device 100 to a host component, such as a printed circuit board (PCB). Host component 299 may be any host component with substrate interconnect interfaces, such as a package host component 299 or interposer, etc. Host component 299 may itself be a die. In many embodiments, host component 299 includes organic dielectric(s), such as a resin or other polymer, between metallization layers.

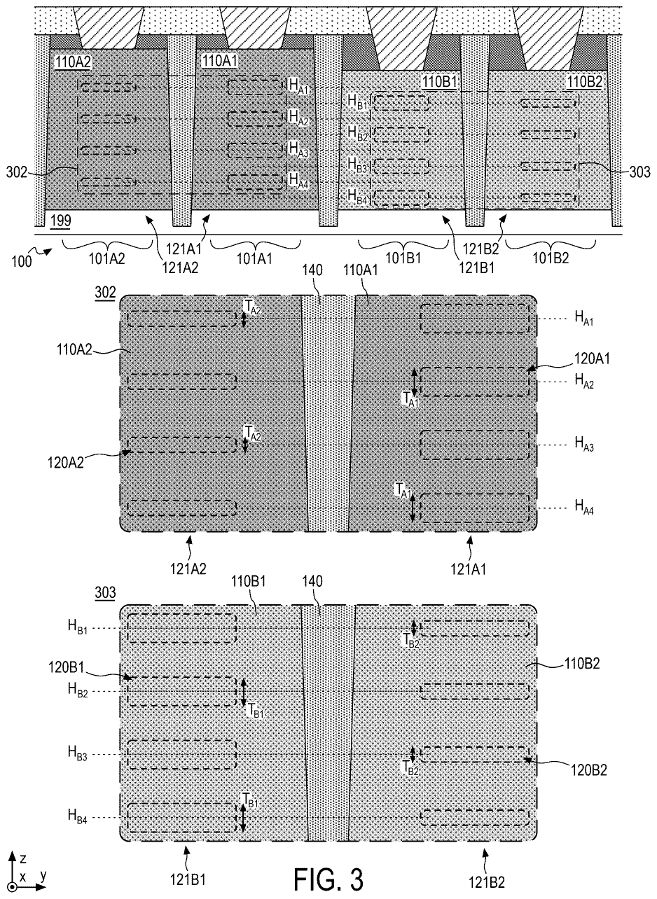

FIG. 3 illustrates cross-sectional profile views of IC device 100 having multiple stacks 121A1, 121A2, 121B1, 121B2 of nanoribbons 120A1, 120A2, 120B1, 120B2 with different thicknesses T_{A1}, T_{A2}, T_{B1}, T_{B2}, in accordance with some embodiments. As described (at least) at FIG. 1, dielectric wall 140 may enable the independent processing of stacks 121A, 121B of nanoribbons 120A, 120B in transistor structures 101A, 101B, which allows for structures 101A, 101B with nanoribbons 120A, 120B of different channel thicknesses and so different threshold voltages V_{T} for a same conductivity type. Having multiple variants available for transistor structures 101A, 101B with different threshold voltages V_{T} enables the optimization of IC device 100 (e.g., by providing low-leakage structures 101A, 101B where beneficial and structures 101A, 101B with faster switching speeds where beneficial).

FIG. 3 (including views 302, 303 of stacks 121A, 121B, respectively) has y-z viewing planes through source or drain bodies 110A1, 110A2, 110B1, 110B2 of multiple transistor structures 101A1, 101A2, 101B1, 101B2. Nanoribbons 120 coupled with (e.g., behind) bodies 110 are shown with dashed outlines. Transistor structures 101A, 101B include nanoribbon stacks 121A, 121B coupled with source or drain bodies 110A, 110B, respectively. Heights H_{A1}- H_{A4} of nanoribbons 120A (e.g., nanoribbons 120A1, 120A2) are offset from and interleaved with heights H_{B1}-H_{B4} of nanoribbons 120B (e.g., nanoribbons 120B1, 120B2).

Magnified view 302 shows stack 121A1 of nanoribbons 120A1 having thicknesses T_{A1} greater than thicknesses T_{A2} of nanoribbons 120A2 in stack 121A2. In some embodiments, nanoribbons 120A1 have thicknesses T_{A1} greater than or equal to four-thirds of thicknesses T_{A2} of nanoribbons 120A2. In the exemplary embodiment of view 302, nanoribbons 120A1, 120A2 have axes centered on the same heights H_{A1}-H_{A4}. In some embodiments, nanoribbons 120A1, 120A2 have axes centered on different heights (e.g., with coplanar surfaces instead).

Magnified view 303 shows stack 121B1 of nanoribbons 120B1 having thicknesses T_{B1} greater than thicknesses T_{B2} of nanoribbons 120B2 in stack 121B2. In some embodiments, nanoribbons 120B1 have thicknesses T_{B1} greater than or equal to four-thirds of thicknesses T_{B2} of nanoribbons 120B2. In the exemplary embodiment of view 303, nanoribbons 120B1, 120B2 have axes centered on the same heights H_{B1}-H_{B4}. In some embodiments, nanoribbons 120B1, 120B2 have axes centered on different heights (e.g., with coplanar surfaces instead). In some embodiments, nanoribbons 120B1 have thicknesses T_{B1} approximately equal to thicknesses T_{A1} of nanoribbons 120A1, and nanoribbons 120B2 have thicknesses T_{B2} approximately equal to thicknesses T_{A2} of nanoribbons 120A2.

FIG. 4 is a flow chart of methods 400 for forming a dielectric wall between two nanoribbon stacks and processing the two nanoribbon stacks independently, in accordance with some embodiments. Methods 400 include operations 401-412. Some operations shown in FIG. 4 are optional. Additional operations may be included. FIG. 4 shows an example sequence, but the operations can be done in other orders as well, and some operations may be omitted. Some operations can also be performed multiple times before other operations are performed. For example, many dielectric walls may be formed between many nanoribbon stacks before further processing the nanoribbon stacks. Some operations may be included within other operations so that the number of operations illustrated FIG. 4 is not a limitation of the methods 400.

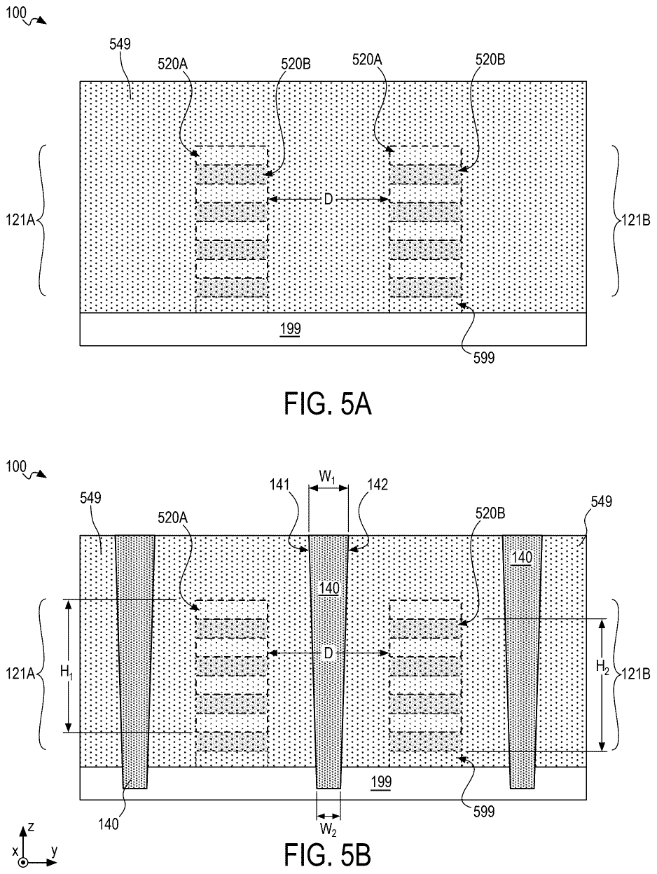

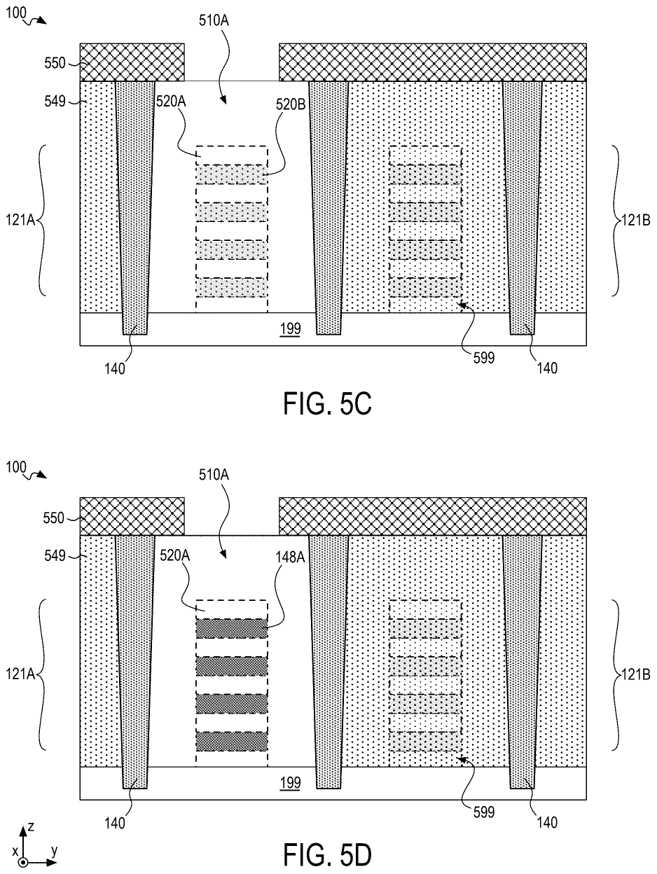

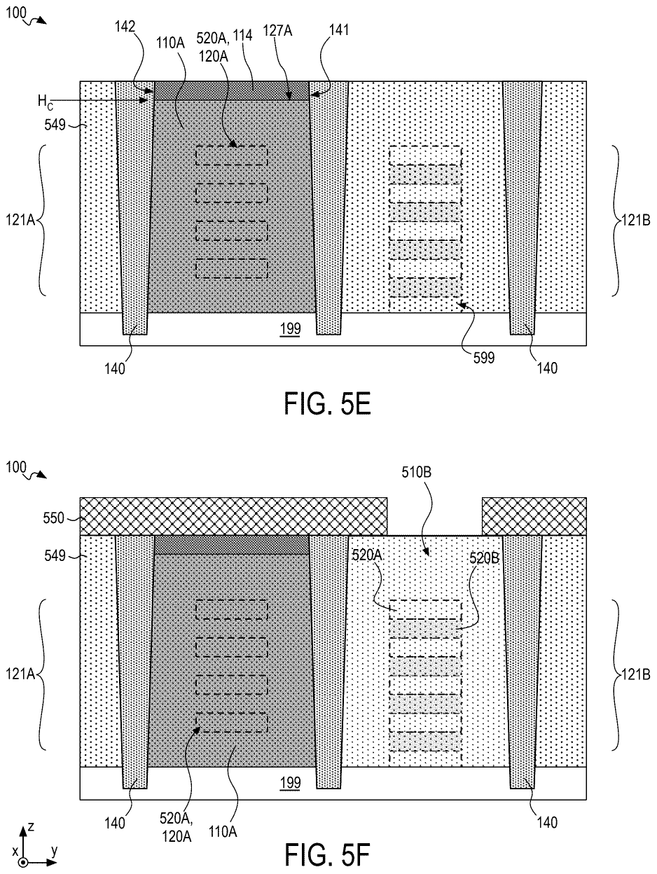

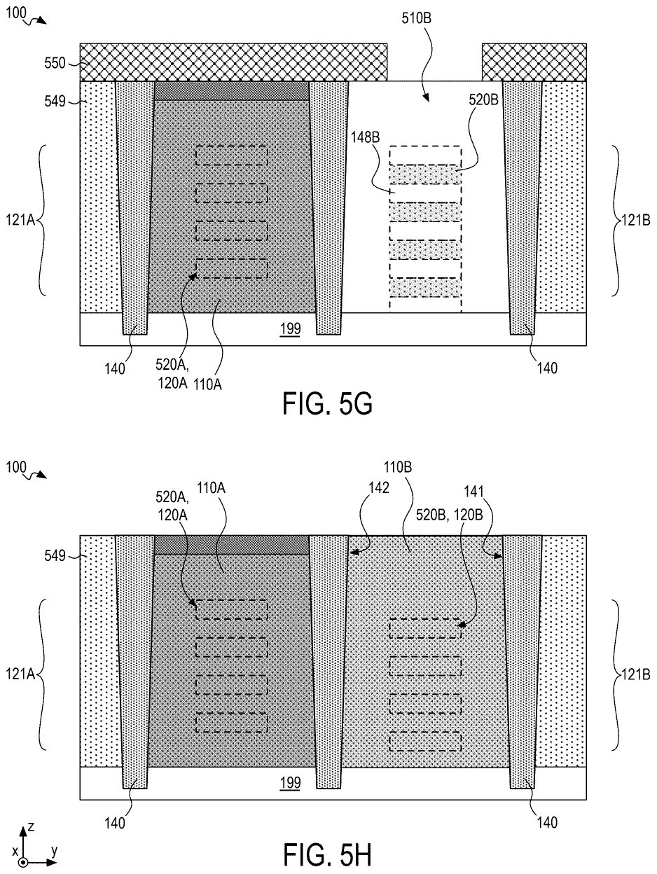

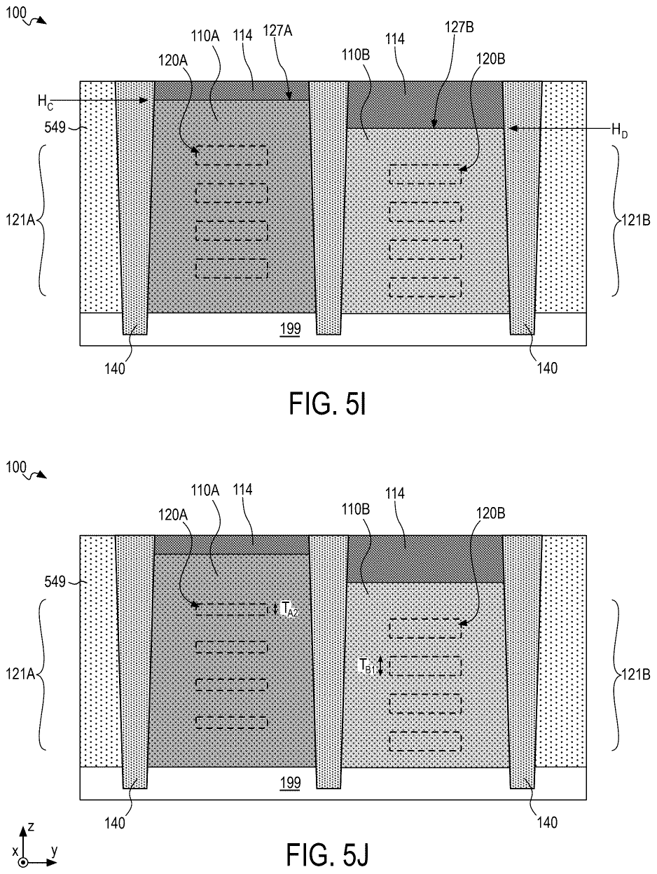

FIGS. 5A, 5B, 5C, 5D, 5E, 5F, 5G, 5H, 5I, and 5J illustrate cross-sectional profile views of IC device 100 having stacks 121A, 121B of nanoribbons 120A, 120B with different characteristics (such as heights and thicknesses), at various stages of manufacture, in accordance with some embodiments. FIGS. 5A-5J show possible examples of intermediate structures during an embodiment of a practice of methods 400 of FIG. 4.

FIG. 5A shows first and second stacks 121A, 121B of alternating first and second material layers 520A, 520B over substrate 199 in a workpiece or IC device 100, in accordance with some embodiments, for example, prior to a performance of forming operation 401. Layers 520A, 520B may be over a subfin 599 portion of substrate 199, which may have a same composition as one of layers 520A, 520B. In some embodiments, first material layers 520A in first stack 121A will be processed into first nanoribbon channel regions in a first transistor, and second material layers 520B in second stack 121B will be processed into second nanoribbon channel regions in a second transistor, vertically offset from the nanoribbon channel regions in the first transistor. For example, first material layers 520A in second stack 121B may be sacrificial material and removed, and second material layers 520B in first stack 121A may be sacrificial material and removed.

The viewing plane of FIG. 5A, etc., is through a trench in front of (e.g., in the x-dimension) first and second material layers 520A, 520B in parallel and similar (e.g., same) stacks 121A, 121B. Dielectric material 549 fills the trench in front of layers 520A, 520B, as well as a parallel trench behind layers 520A, 520B. Dielectric material 549 may be any suitable material, such as a low-k dielectric material.

Material layers 520A, 520B are behind the viewing plane of FIG. 5A, etc., but are shown with dashed outlines, e.g., for reference. Other structures behind the viewing plane, such as a possible dummy gate, etc., over layers 520A, 520B, are not shown. Though not in the viewing plane, material layers 520A, 520B are shown with different shading to highlight the different material compositions of layers 520A, 520B.

Layers 520A, 520B may be of any suitable material(s), for example, semiconducting materials having etch selectivities with each other. In many embodiments, first material layers 520A are predominantly silicon (e.g., for n-type channels), and second material layers 520B include silicon and germanium (e.g., for p-type channels).

Layer stacks 121A, 121B are separated by distance D, which may be made advantageously small due to the processing operation of methods 400, for example, that enable the processing of stacks 121A, 121B and layers 520A, 520B with the minimal separation of distance D. For example, distance D may be 40 nm or less.

Returning to FIG. 4, methods 400 begin at operation 401 with forming a dielectric wall between first and second stacks of alternating first and second material layers. The first and second stacks of first and second material layers may be received on or in a substrate, such as an IC die or wafer, e.g., much as described of substrate 199 at FIG. 1. The material layer stacks may be formed by any suitable means and of any suitable material(s). In many embodiments, the first and second material layers are deposited in a single stack of semiconducting material layers with mutual etch selectivities, and the stacks are cut up (e.g., etched) into many parallel, smaller stacks (e.g., fins) of first and second material layers. In some such embodiments, the smaller stacks or fins of first and second material layers are cut (e.g., in an orthogonal direction) to form more, smaller stacks or fins of first and second material layers aligned on a shared centerline or axis. In many embodiments, some of the parallel stacks are of alternating, complementary conductivity types (e.g., n-and p-types), and adjacent aligned (e.g., in-line) stacks or fins include channel layers that will share source or drain bodies grown in trenches between the adjacent fins. In many embodiments, first material layers are predominantly silicon (e.g., for n-type channels), and second material layers include silicon and germanium (e.g., for p-type channels).

The dielectric wall may be formed by any suitable means and of any suitable material(s). In many embodiments, forming the dielectric wall includes opening (e.g., etching) a cavity through a first dielectric material, for example, in a trench between pairs of first and second stacks of first and second layers (e.g., beyond ends of the first and second stacks of first and second layers). The etch may be an anisotropic etch (e.g., a plasma etch, in a line parallel to the layers and stacks). The etch may have a minimal width, for example, of 15 nm or less. The etch width may be less than a third of the height of the layer stacks.

The first dielectric material may be in many, parallel trenches with pairs of stacks (e.g., many, many stacks of first and second layers) between each adjacent pair of parallel trenches. The etched-open cavity may be through many parallel trenches, for example, extending substantially parallel to the first and second stacks of first and second material layers and beyond ends of the first and second stacks of first and second material layers (e.g., with the cavity longer than the material layers). A dummy gate may be over the first and second stacks and may extend in a direction substantially orthogonal to the first and second stacks of first and second material layers, and the cavity may be etched through the dummy gate, as well as through spacer dielectrics on sidewalls of the dummy gate, between the dummy gate and the dielectric trenches.

The dielectric wall may be formed by depositing a second dielectric material in the etched-open cavity (parallel with the material layers and stacks). The dielectric wall may be formed concurrently with many other dielectric walls, e.g., parallel dielectric walls on both sides of the many parallel material layers and stacks, all formed by concurrent etches and concurrent dielectric depositions. The concurrent wall formations may leave each material layer stack tightly bracketed or bookended by a pair of dielectric walls.

The dielectric wall may include any suitable dielectric material, e.g., a material with etch selectivities with adjacent materials. For example, the deposited second dielectric material advantageously has good etch selectivities with the first dielectric material in the trenches at ends of the material layer stacks and with the sacrificial material of the dummy gate, both of which may be subsequently removed while the dielectric wall is retained. A spacer dielectric material may also be retained. Advantageously, the deposited (e.g., second) dielectric material is a low-k dielectric material. In many embodiments, depositing the second dielectric material deposits silicon and nitrogen, for example, with a CVD (chemical vapor deposition) or ALD (atomic layer deposition).

FIG. 5B illustrates dielectric wall 140 between stacks 121A, 121B of layers 520A, 520B in workpiece or device 100, in accordance with some embodiments, for example, following a performance of forming operation 401. Walls 140 include sidewalls 141, 142 and extend through dielectric material 549, beyond and below the bottoms of stacks 121A, 121B, for example, into substrate 199. Dielectric walls 140 may have minimal widths W₁, W₂, for example, of 12 nm or less.

Returning to FIG. 4, methods 400 continue by opening a first cavity on a first side of the dielectric wall at operation 402. In many embodiments, opening the first cavity exposes first ends (e.g., sidewalls) of the first and second material layers in the first cavity, e.g., in the first material stack. The exposing the first ends of the first and second layers in the first stack may make the first ends available for further processing, while second ends of the first and second layers in the second stack may be kept masked (e.g., by the first, trench dielectric) on a second side of the dielectric wall.

The first cavity may be opened by any suitable means, for example, by patterning a rigid mask layer over the substrate with a mask opening over the first material layer stack and by isotropically (e.g., selectively) removing the first dielectric material in the trench. The exposing etch may expose other stack ends (e.g., first ends) to be concurrently processed. For example, the opposite ends of the first and second material layers in the first material stack may be first ends exposed in a first cavity and concurrently processed (e.g., on the same first side of the same dielectric wall).

FIG. 5C shows first cavity 510A over first stack 121A in workpiece or device 100, in accordance with some embodiments, for example, following a performance of opening operation 402. Mask layer 550 is over walls 140 and dielectric material 549, including over second stack 121B. Material layers 520A, 520B (still behind the viewing plane and shown dashed) are available for processing in first cavity 510A and first stack 121A, but not in second stack 121B.

Returning to FIG. 4, methods 400 continue with recessing the second material layers in the first cavity at operation 403. The recessing the second material layers (e.g., of the first stack) in the first cavity at operation 403 may be part of a replacing operation (e.g., that also includes forming operation 404) that replaces the first ends of the second material layers with first cavity spacers between the first ends of the first material layers. The first ends of the second material layers (e.g., in the first stack) may be recessed by any suitable means, for example, by a selective etch of the exposed (first ends of the) second material layers in the first cavity. The selective etch may isotropically remove the sacrificial second material layers in the first stack and leave or retain other exposed materials such as the first (e.g., channel) material layers and any exposed materials (such as spacer dielectric material sidewalls, a rigid mask layer, etc.).

Returning to FIG. 4, methods 400 continue at operation 404 by forming first cavity spacers between the first ends of the first material layers. The forming first cavity spacers (e.g., in the first stack) in the first cavity at operation 404 may be part of a replacing operation (e.g., that also includes recessing operation 403) that replaces the first ends of the second material layers with the first cavity spacers. The first cavity spacers may be formed by any suitable means, for example, by selectively depositing a dielectric material adjacent (e.g., on) the recessed first ends of the second material layers in the first stack and in the first cavity. In some embodiments, the dielectric material is conformally deposited (e.g., less selectively). In some embodiments, the dielectric material is recessed back, for example, with an anisotropic etch that removes excess first cavity spacer dielectric material and retains only first cavity spacer dielectric material adjacent the recessed first ends of the second material layers in the first stack, e.g., between the first ends of the first material layers.

FIG. 5D illustrates first cavity spacers 148A between channel material layers 520A in first cavity 510A and first stack 121A in workpiece or device 100, in accordance with some embodiments, for example, following a performance of recessing and forming operations 403 and 404.

Returning to FIG. 4, methods 400 continue at operation 405 with growing a first source or drain body on first ends of the first material layers. The first source or drain body may be grown by any suitable means and of any suitable material(s). In many embodiments, the first source or drain body is epitaxially grown on and from the exposed first ends of the first material layers in the first material stack (and first cavity only). With only the first cavity (or first cavities) available for processing (e.g., with the second stacks covered by the trench dielectric, and most of the substrate by a mask layer), the first source or drain body (or bodies) can be grown to a well-controlled and desired volume, for example, to an advantageously larger volume.

The first source or drain body (or bodies) may be grown to fill the first cavity. In many embodiments, the first source or drain body is grown out to the dielectric walls defining the first cavity (or first cavities), e.g., with sidewalls of the first source or drain body contacting dielectric walls to both sides of the first source or drain body. Larger source or drain body volumes may improve body conductivity, e.g., by increasing cross-sectional areas for conduction between lower nanoribbon channel regions and a contact on an upper surface of the source or drain body. The first source or drain body may include any suitable material(s), for example, a semiconducting or conducting (e.g., heavily doped) material, much as described of bodies 110 at FIG. 1.

FIG. 5E shows first source or drain body 110A between dielectric walls 140 (e.g., filling what may have been a first cavity) and coupled with channel material layers 520A (e.g., nanoribbons 120A) in workpiece or device 100, in accordance with some embodiments, for example, following a performance of growing operation 405. Second, sacrificial material layers 520B (not shown) may still be behind the viewing plane (and now body 110A), but channel material layers 520A or nanoribbons 120A are coupled to first source or drain body 110A, with first cavity spacers 148A (not shown) between nanoribbons 120A and between body 110A and sacrificial material layers 520B (not shown). First source or drain body 110A is in contact with adjacent dielectric walls 140 (e.g., at sidewalls 141, 142) to both sides of body 110A. First source or drain body 110A has an upper surface 127A at a reduced height H_{C} (e.g., following a recessing operation 410, described elsewhere herein), and dielectric layer 114 is over body 110A, on surface 127A. Recessing operation 410 may conveniently be performed on first body 110A following a forming at operation 405, for example, while a patterned mask layer still covers stack 121B.

Returning to FIG. 4, methods 400 continue by opening a second cavity on a second side of the dielectric wall at operation 406. Opening the second cavity on the second side of the dielectric wall at operation 406 may be much like opening the first cavity on the first side of the dielectric wall at operation 402. The opening the second cavity may expose second ends (e.g., sidewalls) of the first and second material layers in the second cavity, in the second material stack. The exposing the second ends of the first and second layers in the second stack may make the second ends available for further processing, while the first ends of the first and second layers in the first stack may be kept masked by the first source or drain body and unprocessed on the first side of the dielectric wall.

The second cavity may be opened by any suitable means, e.g., by patterning a mask opening over the second material layer stack and by selectively removing the trench dielectric material. The exposing etch may expose other stack ends (e.g., second ends in second cavities) to be concurrently processed. For example, the opposite ends of the first and second material layers in the second material stack may be second ends exposed in a second cavity and concurrently processed.

FIG. 5F illustrates second cavity 510B over second stack 121B in workpiece or device 100, in accordance with some embodiments, for example, following a performance of opening operation 406. Mask layer 550 is over first source or drain body 110A, dielectric walls 140, and dielectric material 549. Material layers 520A, 520B are available for processing in second stack 121B and second cavity 510B.

Returning to FIG. 4, methods 400 continue with recessing the first or second material layers in the second cavity at operation 407. The recessing at operation 407 may be similar to the recessing in the first cavity at operation 403. Notably, in many embodiments, the first material layers are recessed in the second cavity, e.g., to provide a different (e.g., optimized) channel material for a complementary nanoribbon stack and transistor. (Stacks having second material layers recessed may be processed in first cavities, concurrently.) For example, having recessed the second material layers of the first stack in the first cavity (e.g., leaving the first material layers of the first stack for channel layers) at operation 403, the second material layers of the second stack may be kept for channel layers in the second cavity. (Recessed second material layers in the first stack and first cavity and recessed first material layers in the second stack and second cavity may be sacrificial material later removed from between channel material layers.)

The recessing material layers of the second stack in the second cavity at operation 407 may be part of a replacing operation (e.g., that also includes forming operation 408) that replaces the second ends of the recessed (first or second) material layers with second cavity spacers between the second ends of the not-recessed (first or second) material layers. The second ends of the (first or second) material layers in the second stack) may be recessed by any suitable means, as in operation 403. For example, a selective etch may expose the second ends of the (first or second) material layers in the second cavity. The selective etch may isotropically remove the sacrificial material layers in the second stack and leave or retain other exposed materials such as the desired channel material layers.

Returning to FIG. 4, methods 400 continue at operation 408 by forming second cavity spacers, e.g., between the second ends of the second material layers. The forming second cavity spacers (e.g., in the second stack) in the second cavity at operation 408 may be part of a replacing operation (e.g., that also includes recessing operation 407) that replaces the second ends of the first material layers with the second cavity spacers. The forming second cavity spacers in the second stack and second cavity at operation 408 may be similar to forming operation 404.

The second cavity spacers may be formed by any suitable means, for example, by selectively depositing a dielectric material adjacent (e.g., on) the recessed second ends of the recessed material layers in the second stack and in the second cavity. In some embodiments, the dielectric material is conformally deposited (e.g., less selectively). In some embodiments, the dielectric material is recessed back, for example, with an anisotropic etch that removes excess second cavity spacer dielectric material and retains only second cavity spacer dielectric material adjacent the recessed second material layer ends in the second stack, e.g., between the second ends of the second material layers.

FIG. 5G shows second cavity spacers 148B between channel material layers 520B in second cavity 510B and second stack 121B in workpiece or device 100, in accordance with some embodiments, for example, following a performance of recessing and forming operations 407 and 408.

Returning to FIG. 4, methods 400 continue at operation 409 with growing a second source or drain body on second ends of the (e.g.) second material layers. The second source or drain body may be grown by any suitable means and of any suitable material(s), for example, as at operation 405. In many embodiments, the second source or drain body is epitaxially grown on and from the exposed second ends of the second material layers in the second material stack (and second cavity only). With only the second cavity (or second cavities) available for processing, the second source or drain body (or bodies) can be grown to a well-controlled and desired volume. In many embodiments, the second source or drain body is grown out to the dielectric walls defining the second cavity (or second cavities), e.g., with sidewalls of the second source or drain body contacting dielectric walls to both sides of the body. The second source or drain body may include any suitable material(s), for example, a semiconducting or conducting (e.g., heavily doped) material, much as described of bodies 110 at FIG. 1.

FIG. 5H illustrates second source or drain body 110B between dielectric walls 140 (e.g., filling what may have been a second cavity) and coupled with channel material layers 520B (e.g., nanoribbons 120B) in workpiece or device 100, in accordance with some embodiments, for example, following a performance of growing operation 409. First, sacrificial material layers 520A (not shown) may still be behind the viewing plane (and now body 110B), but channel material layers 520B or nanoribbons 120B are coupled to second source or drain body 110B, with second cavity spacers 148B (not shown) between nanoribbons 120B and between body 110B and sacrificial material layers 520A (not shown). Second source or drain body 110B is in contact with adjacent dielectric walls 140 (e.g., at sidewalls 141, 142) to both sides of body 110B.

Returning to FIG. 4, methods 400 continue by recessing an upper surface of the first or second source or drain bodies at operation 410. Recessing an upper surface of the first or second (or both) source or drain bodies may reduce a height of the source or drain body and so reduce parasitic capacitances with adjacent structures, such as gate electrodes. An upper surface of either or both of the first or second source or drain bodies may be recessed, for example, when that source or drain body is being independently processed in the body's respective first or second cavity (e.g., on the respective first or second side of the dielectric wall). The first or second source or drain body may be recessed by a selective, isotropic etch of the source or drain material. In some embodiments, one or both source or drain bodies are recessed by an isotropic etch, for example, using another mask following source and drain growth. The one or both source or drain bodies may be recessed to different heights or depths, e.g., to minimize parasitic capacitances.

An isolation layer of dielectric material may be deposited over one or both source or drain bodies, e.g., to later be contacted through by a contact via.

FIG. 5I shows first and second source or drain bodies 110A, 110B having upper surfaces 127 with different heights H_{C}, H_{D} in workpiece or device 100, in accordance with some embodiments, for example, following a performance of recessing operation 410. First source or drain body 110A has an upper surface 127A at height H_{C}, above upper surface 127B of second source or drain body 110B at height H_{D}. Insulation layers 114 are over both of bodies 110A, 110B.

Returning to FIG. 4, methods 400 continue with releasing the first and/or second material layers at operation 411. The channel material layers to be retained (e.g., first and second material layers coupled with the first and second source or drain bodies) may be released by removing the sacrificial material layers adjacent (e.g., in the same stack, between) to the channel material layers. The sacrificial material layers may be those recessed at operations 403 and 407. The dielectric wall separating the first and second stacks may enable the separate release of channel material layers and removal of sacrificial material layers in the different stacks, including the retention of a first material and removal of a second material in a first stack and the retention of the second material and removal of the first material in a second stack.

The first and/or second material layers may be released by any suitable means. In some embodiments, the releasing the first and/or second material layers includes opening third and fourth cavities on the first and second sides of the dielectric wall separating the first and second stacks. In some embodiments, the opening third and fourth cavities on the first and second sides of the dielectric wall includes removing a dummy gate (e.g., multiple dummy gate portions now separated by the dielectric wall) from over the first and second layer stacks. Removing the dummy gate(s) may open the cavities over the layer stacks and between spacer walls that were separating the dummy gate(s) from the grown source and drain bodies. The dummy gate(s) may be removed by any suitable means, such as a selective etch. The third and fourth cavities may be masked and patterned over and processed independently much as the first and second cavities were.

The sacrificial material layers may be removed by any suitable means, for example, selective etches employing etch selectivities between the first and second material layers. In many embodiments, the second material layers are removed and the first material layers are retained in the first layer stack and third cavity (e.g., on the first side of the dielectric wall), and the first material layers are removed and the second material layers are retained in the second layer stack and fourth cavity (e.g., on the second side of the dielectric wall). Removing the different material layers on the different sides of the dielectric wall may result in adjacent first and second stacks of channel material layers (e.g., nanoribbons) with offset and interleaved heights.

Returning to FIG. 4, methods 400 continue at operation 412 by thinning the first or second (e.g., channel) material layers. The separate third and fourth cavities may enable the thinning of one or the other of the first or second material layers in only one of the third and fourth cavities, but layers in both the third and fourth cavities (and first and second stacks) may be thinned. The first or second (e.g., channel) material layers may be thinned by any suitable means, for example, by isotropically etching the layers. In some embodiments, the layer thinning may be done concurrently with removing the sacrificial material layers (e.g., by an over-etch).

FIG. 5J illustrates nanoribbons 120A, 120B with different thicknesses T_{A2}, T_{B1} and offset heights in different stacks 121A, 121B in IC device 100, in accordance with some embodiments, for example, following a performance of releasing and thinning operations 411 and 412. Thicknesses T_{A2} of nanoribbons 120A are less (e.g., shorter) than thicknesses T_{B1} of nanoribbons 120B.

Source or drain bodies 110A, 110B may subsequently be coupled to an interconnect network (not shown) by contacts and vias (not shown). Gate structures with gate electrodes (not shown) may be formed over nanoribbons 120A, 120B, e.g., between bodies 110A, 110B in FIG. 5J and other bodies 110A, 110B on the other sides and ends of nanoribbons 120A, 120B.

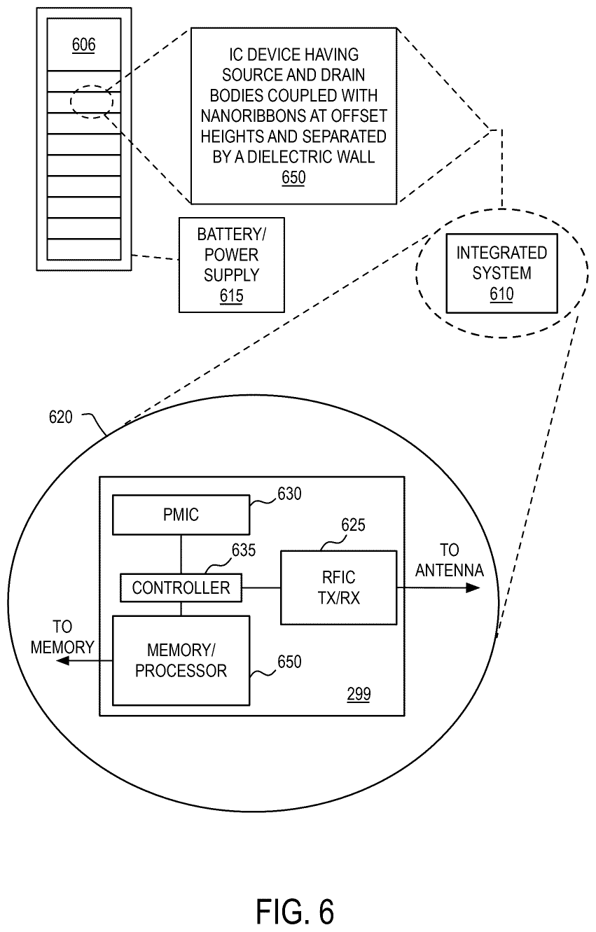

FIG. 6 illustrates a diagram of an example data server machine 606 employing an IC device having source and drain bodies coupled with offset nanoribbons and separated by dielectric walls, in accordance with some embodiments. Server machine 606 may be any commercial server, for example, including any number of high-performance computing platforms disposed within a rack and networked together for electronic data processing, which in the exemplary embodiment includes one or more devices 650 having source and drain bodies coupled with offset nanoribbons and separated by dielectric walls.

Also as shown, server machine 606 includes a battery and/or power supply 615 to provide power to devices 650, and to provide, in some embodiments, power delivery functions such as power regulation. Devices 650 may be deployed as part of a package-level integrated system 610. Integrated system 610 is further illustrated in the expanded view 620. In the exemplary embodiment, devices 650 (labeled “Memory/Processor”) includes at least one memory chip (e.g., random-access memory (RAM)), and/or at least one processor chip (e.g., a microprocessor, a multi-core microprocessor, or graphics processor, or the like) having the characteristics discussed herein. In an embodiment, device 650 is a microprocessor including a static RAM (SRAM) cache memory. As shown, device 650 may be an IC device having source and drain bodies coupled with offset nanoribbons and separated by dielectric walls, as discussed herein. Device 650 may be further coupled to (e.g., communicatively coupled to) a board, an interposer, or other substrate or host component 299 along with, one or more of a power management IC (PMIC) 630, RF (wireless) IC (RFIC) 625 including a wideband RF (wireless) transmitter and/or receiver (TX/RX) (e.g., including a digital baseband and an analog front-end module further includes a power amplifier on a transmit path and a low noise amplifier on a receive path), and a controller 635 thereof. In some embodiments, RFIC 625, PMIC 630, controller 635, and device 650 include having source and drain bodies coupled with offset nanoribbons and separated by dielectric walls.

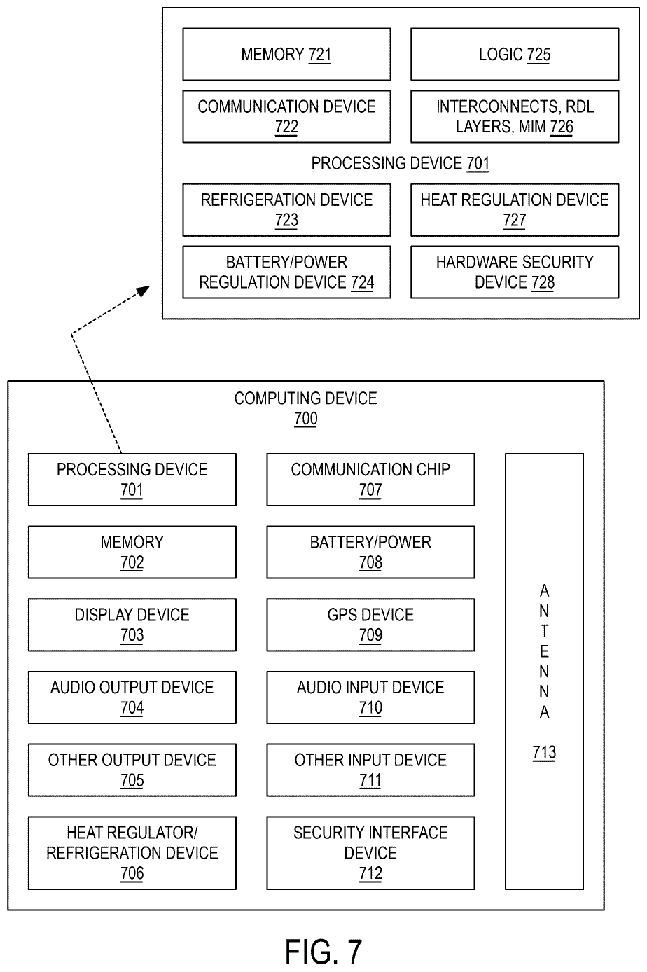

FIG. 7 is a block diagram of an example computing device 700, in accordance with some embodiments. For example, one or more components of computing device 700 may include any of the devices or structures discussed herein. A number of components are illustrated in FIG. 7 as being included in computing device 700, but any one or more of these components may be omitted or duplicated, as suitable for the application. In some embodiments, some or all of the components included in computing device 700 may be attached to one or more printed circuit boards (e.g., a motherboard). In some embodiments, various ones of these components may be fabricated onto a single system-on-a-chip (SoC) die. Additionally, in various embodiments, computing device 700 may not include one or more of the components illustrated in FIG. 7, but computing device 700 may include interface circuitry for coupling to the one or more components. For example, computing device 700 may not include a display device 703, but may include display device interface circuitry (e.g., a connector and driver circuitry) to which display device 703 may be coupled. In another set of examples, computing device 700 may not include an audio output device 704, other output device 705, global positioning system (GPS) device 709, audio input device 710, or other input device 711, but may include audio output device interface circuitry, other output device interface circuitry, GPS device interface circuitry, audio input device interface circuitry, audio input device interface circuitry, to which audio output device 704, other output device 705, GPS device 709, audio input device 710, or other input device 711 may be coupled.

Computing device 700 may include a processing device 701 (e.g., one or more processing devices). As used herein, the term “processing device” or “processor” indicates a device that processes electronic data from registers and/or memory to transform that electronic data into other electronic data that may be stored in registers and/or memory. Processing device 701 may include a memory 721, a communication device 722, a refrigeration device 723, a battery/power regulation device 724, logic 725, interconnects 726 (i.e., optionally including redistribution layers (RDL) or metal-insulator-metal (MIM) devices), a heat regulation device 727, and a hardware security device 728.

Processing device 701 may include one or more digital signal processors (DSPs), application-specific ICs (ASICs), central processing units (CPUs), graphics processing units (GPUs), cryptoprocessors (specialized processors that execute cryptographic algorithms within hardware), server processors, or any other suitable processing devices.

Computing device 700 may include a memory 702, which may itself include one or more memory devices such as volatile memory (e.g., dynamic random-access memory (DRAM)), nonvolatile memory (e.g., read-only memory (ROM)), flash memory, solid state memory, and/or a hard drive. In some embodiments, memory 702 includes memory that shares a die with processing device 701. This memory may be used as cache memory and may include embedded dynamic random-access memory (eDRAM) or spin transfer torque magnetic random-access memory (STT-MRAM).

Computing device 700 may include a heat regulation/refrigeration device 706. Heat regulation/refrigeration device 706 may maintain processing device 701 (and/or other components of computing device 700) at a predetermined low temperature during operation.

In some embodiments, computing device 700 may include a communication chip 707 (e.g., one or more communication chips). For example, the communication chip 707 may be configured for managing wireless communications for the transfer of data to and from computing device 700. The term “wireless” and its derivatives may be used to describe circuits, devices, systems, methods, techniques, communications channels, etc., that may communicate data through the use of modulated electromagnetic radiation through a nonsolid medium. The term does not imply that the associated devices do not contain any wires, although in some embodiments they might not.

Communication chip 707 may implement any of a number of wireless standards or protocols, including but not limited to Institute for Electrical and Electronic Engineers (IEEE) standards including Wi-Fi (IEEE 802.11 family), IEEE 802.16 standards (e.g., IEEE 802.16-2005 Amendment), Long-Term Evolution (LTE) project along with any amendments, updates, and/or revisions (e.g., advanced LTE project, ultramobile broadband (UMB) project (also referred to as “3GPP2”), etc.). IEEE 802.16 compatible Broadband Wireless Access (BWA) networks are generally referred to as WiMAX networks, an acronym that stands for Worldwide Interoperability for Microwave Access, which is a certification mark for products that pass conformity and interoperability tests for the IEEE 802.16 standards. Communication chip 707 may operate in accordance with a Global System for Mobile Communication (GSM), General Packet Radio Service (GPRS), Universal Mobile Telecommunications System (UMTS), High Speed Packet Access (HSPA), Evolved HSPA (E-HSPA), or LTE network. Communication chip 707 may operate in accordance with Enhanced Data for GSM Evolution (EDGE), GSM EDGE Radio Access Network (GERAN), Universal Terrestrial Radio Access Network (UTRAN), or Evolved UTRAN (E-UTRAN). Communication chip 707 may operate in accordance with Code Division Multiple Access (CDMA), Time Division Multiple Access (TDMA), Digital Enhanced Cordless Telecommunications (DECT), Evolution-Data Optimized (EV-DO), and derivatives thereof, as well as any other wireless protocols that are designated as 3G, 4G, 5G, and beyond. Communication chip 707 may operate in accordance with other wireless protocols in other embodiments. Computing device 700 may include an antenna 713 to facilitate wireless communications and/or to receive other wireless communications (such as AM or FM radio transmissions).

In some embodiments, communication chip 707 may manage wired communications, such as electrical, optical, or any other suitable communication protocols (e.g., the Ethernet). As noted above, communication chip 707 may include multiple communication chips. For instance, a first communication chip 707 may be dedicated to shorter-range wireless communications such as Wi-Fi or Bluetooth, and a second communication chip 707 may be dedicated to longer-range wireless communications such as GPS, EDGE, GPRS, CDMA, WiMAX, LTE, EV-DO, or others. In some embodiments, a first communication chip 707 may be dedicated to wireless communications, and a second communication chip 707 may be dedicated to wired communications.

Computing device 700 may include battery/power circuitry 708. Battery/power circuitry 708 may include one or more energy storage devices (e.g., batteries or capacitors) and/or circuitry for coupling components of computing device 700 to an energy source separate from computing device 700 (e.g., AC line power).

Computing device 700 may include a display device 703 (or corresponding interface circuitry, as discussed above). Display device 703 may include any visual indicators, such as a heads-up display, a computer monitor, a projector, a touchscreen display, a liquid crystal display (LCD), a light-emitting diode display, or a flat panel display, for example.

Computing device 700 may include an audio output device 704 (or corresponding interface circuitry, as discussed above). Audio output device 704 may include any device that generates an audible indicator, such as speakers, headsets, or earbuds, for example.

Computing device 700 may include an audio input device 710 (or corresponding interface circuitry, as discussed above). Audio input device 710 may include any device that generates a signal representative of a sound, such as microphones, microphone arrays, or digital instruments (e.g., instruments having a musical instrument digital interface (MIDI) output).

Computing device 700 may include a GPS device 709 (or corresponding interface circuitry, as discussed above). GPS device 709 may be in communication with a satellite-based system and may receive a location of computing device 700, as known in the art.

Computing device 700 may include other output device 705 (or corresponding interface circuitry, as discussed above). Examples of the other output device 705 may include an audio codec, a video codec, a printer, a wired or wireless transmitter for providing information to other devices, or an additional storage device.

Computing device 700 may include other input device 711 (or corresponding interface circuitry, as discussed above). Examples of the other input device 711 may include an accelerometer, a gyroscope, a compass, an image capture device, a keyboard, a cursor control device such as a mouse, a stylus, a touchpad, a bar code reader, a Quick Response (QR) code reader, any sensor, or a radio frequency identification (RFID) reader.

Computing device 700 may include a security interface device 712. Security interface device 712 may include any device that provides security measures for computing device 700 such as intrusion detection, biometric validation, security encode or decode, access list management, malware detection, or spyware detection.

Computing device 700, or a subset of its components, may have any appropriate form factor, such as a hand-held or mobile computing device (e.g., a cell phone, a smart phone, a mobile internet device, a music player, a tablet computer, a laptop computer, a netbook computer, a personal digital assistant (PDA), an ultramobile personal computer, etc.), a desktop computing device, a server or other networked computing component, a printer, a scanner, a monitor, a set-top box, an entertainment control unit, a vehicle control unit, a digital camera, a digital video recorder, or a wearable computing device.

The subject matter of the present description is not necessarily limited to specific applications illustrated in FIGS. 1-7. The subject matter may be applied to other deposition applications, as well as any appropriate manufacturing application, as will be understood to those skilled in the art.

The following examples pertain to further embodiments, and specifics in the examples may be used anywhere in one or more embodiments.

In one or more first embodiments, an apparatus includes a first source or drain body coupled with a stack of first nanoribbons in a first transistor structure, a second source or drain body coupled with a stack of second nanoribbons in a second transistor structure, wherein each adjacent pair of the second nanoribbons includes upper and lower second nanoribbons, the upper second nanoribbon with a first height above a second height of an adjacent first nanoribbon and the lower second nanoribbon with a third height below the second height of the adjacent first nanoribbon, and a dielectric structure between the stacks of first and second nanoribbons, the dielectric structure separating the first and second source or drain bodies.

In one or more second embodiments, further to the first embodiments, the dielectric structure is between and in contact with the first and second source or drain bodies.

In one or more third embodiments, further to the first or second embodiments, the dielectric structure is a first dielectric structure, and the apparatus also includes second and third dielectric structures, the first source or drain body between and in contact with the first and second dielectric structures, the second source or drain body between and in contact with the first and third dielectric structures.

In one or more fourth embodiments, further to the first through third embodiments, a fourth height of a first upper surface of the first source or drain body is greater than a fifth height of a second upper surface of the second source or drain body.

In one or more fifth embodiments, further to the first through fourth embodiments, the first nanoribbons have a first thickness greater than a second thickness of the second nanoribbons.

In one or more sixth embodiments, further to the first through fifth embodiments, the first transistor structure includes a first gate electrode, a first dielectric material is between adjacent first nanoribbons and between the first gate electrode and the first source or drain body, the second transistor structure includes a second gate electrode, and a second dielectric material is between adjacent second nanoribbons and between the second gate electrode and the second source or drain body, the second dielectric material having a first composition different than a second composition of the first dielectric material.

In one or more seventh embodiments, further to the first through sixth embodiments, the first nanoribbons are predominantly silicon and the second nanoribbons include silicon and germanium.

In one or more eighth embodiments, further to the first through seventh embodiments, the first source or drain body is predominantly silicon and the second source or drain body includes silicon and germanium.

In one or more ninth embodiments, further to the first through eighth embodiments, the stack of first nanoribbons has a first height approximately equal to a second height of the stack of second nanoribbons.

In one or more tenth embodiments, an apparatus includes a first transistor structure including a stack of first nanoribbons coupled with a first source or drain body, a second transistor structure including a stack of second nanoribbons coupled with a second source or drain body, wherein first heights of the first nanoribbons are interleaved with second heights of the second nanoribbons, and a dielectric wall between and in contact with the first and second source or drain bodies.

In one or more eleventh embodiments, further to the tenth embodiments, the dielectric structure is a first dielectric structure, the first source or drain body is between and in contact with the first dielectric structure and a second dielectric structure, and the second source or drain body between and in contact with the first dielectric structure and a third dielectric structure.

In one or more twelfth embodiments, further to the tenth or eleventh embodiments, the first nanoribbons extend through a first gate electrode, the second nanoribbons extend through a second gate electrode, and the dielectric structure is between the first and second gate electrodes.

In one or more thirteenth embodiments, further to the tenth through twelfth embodiments, the first nanoribbons have a first thickness greater than a second thickness of the second nanoribbons.

In one or more fourteenth embodiments, further to the tenth through thirteenth embodiments, the apparatus is coupled to a host component, and the apparatus is coupled to a power supply through the host component.

In one or more fifteenth embodiments, a method includes forming a dielectric wall between first and second stacks of alternating first and second material layers over a substrate, opening a first cavity on a first side of the dielectric wall, wherein first ends of the first and second material layers are exposed in the first cavity, replacing the first ends of the second material layers with first cavity spacers, growing a first source or drain body on first ends of the first material layers, opening a second cavity on a second side of the dielectric wall, wherein second ends of the first and second material layers are exposed in the second cavity, replacing the second ends of the first or second material layers with second cavity spacers, and growing a second source or drain body on second ends of the second or first material layers.

In one or more sixteenth embodiments, further to the fifteenth embodiments, the forming the dielectric wall between the first and second stacks includes etching through a dummy gate over the first and second stacks of the first and second material layers, and also including opening third and fourth cavities on the first and second sides of the dielectric wall by removing first and second portions of the dummy gate, removing the second material layers in the third cavity, and removing the first material layers in the fourth cavity.

In one or more seventeenth embodiments, further to the fifteenth or sixteenth embodiments, forming the dielectric wall forms first and second dielectric walls, and growing the first or second source or drain body grows the first or second source or drain body to contact the first and second dielectric walls to third and fourth sides of the first or second source or drain body.

In one or more eighteenth embodiments, further to the fifteenth through seventeenth embodiments, the method also includes recessing an upper surface of the second source or drain body to a first height lower than a second height of an upper surface of the first source or drain body.

In one or more nineteenth embodiments, further to the fifteenth through eighteenth embodiments, the method also includes thinning the first material layers to a first thickness less than a second thickness of the second material layers.

In one or more twentieth embodiments, further to the fifteenth through nineteenth embodiments, the forming the dielectric wall between the first and second stacks of first and second material layers includes opening a fifth cavity through a first dielectric material, wherein the fifth cavity extends substantially parallel to the first and second stacks of first and second material layers and through a dummy gate extending in a direction substantially orthogonal to the first and second stacks of first and second material layers, and depositing a second dielectric material in the fifth cavity, opening the first cavity on the first side of the dielectric wall opens a first pair of first cavities on the first side of the dielectric wall, the first stack of first and second material layers between the first cavities, opening the second cavity on the second side of the dielectric wall opens a second pair of second cavities on the second side of the dielectric wall, the second stack of first and second material layers between the second cavities, growing the first source or drain body grows a first pair of first source or drain bodies in the first cavities, and growing the second source or drain body grows a second pair of second source or drain bodies in the second cavities.

The disclosure can be practiced with modification and alteration, and the scope of the appended claims is not limited to the embodiments so described. For example, the above embodiments may include specific combinations of features. However, the above embodiments are not limiting in this regard and, in various implementations, the above embodiments may include the undertaking only a subset of such features, undertaking a different order of such features, undertaking a different combination of such features, and/or undertaking additional features than those features explicitly listed. The scope of the patent rights should, therefore, be determined with reference to the appended claims, along with the full scope of equivalents to which such claims are entitled.

We claim:

1. An apparatus, comprising:
a first source or drain body coupled with a stack of first nanoribbons in a first transistor structure;
a second source or drain body coupled with a stack of second nanoribbons in a second transistor structure, wherein each adjacent pair of the second nanoribbons includes upper and lower second nanoribbons, the upper second nanoribbon with a first height above a second height of an adjacent first nanoribbon and the lower second nanoribbon with a third height below the second height of the adjacent first nanoribbon; and
a dielectric structure between the stacks of first and second nanoribbons, the dielectric structure separating the first and second source or drain bodies.

2. The apparatus of claim 1, wherein the dielectric structure is between and in contact with the first and second source or drain bodies.

3. The apparatus of claim 1, wherein the dielectric structure is a first dielectric structure, further comprising second and third dielectric structures, the first source or drain body between and in contact with the first and second dielectric structures, the second source or drain body between and in contact with the first and third dielectric structures.

4. The apparatus of claim 1, wherein a fourth height of a first upper surface of the first source or drain body is greater than a fifth height of a second upper surface of the second source or drain body.

5. The apparatus of claim 1, wherein the first nanoribbons have a first thickness greater than a second thickness of the second nanoribbons.

6. The apparatus of claim 1, wherein:
the first transistor structure comprises a first gate electrode;
a first dielectric material is between adjacent first nanoribbons and between the first gate electrode and the first source or drain body;
the second transistor structure comprises a second gate electrode; and
a second dielectric material is between adjacent second nanoribbons and between the second gate electrode and the second source or drain body, the second dielectric material having a first composition different than a second composition of the first dielectric material.

7. The apparatus of claim 6, wherein the first nanoribbons are predominantly silicon and the second nanoribbons comprise silicon and germanium.

8. The apparatus of claim 7, wherein the first source or drain body is predominantly silicon and the second source or drain body comprises silicon and germanium.

9. The apparatus of claim 1, wherein the stack of first nanoribbons has a first height approximately equal to a second height of the stack of second nanoribbons.

10. An apparatus, comprising:
a first transistor structure comprising a stack of first nanoribbons coupled with a first source or drain body;
a second transistor structure comprising a stack of second nanoribbons coupled with a second source or drain body, wherein first heights of the first nanoribbons are interleaved with second heights of the second nanoribbons; and
a dielectric wall between and in contact with the first and second source or drain bodies.

11. The apparatus of claim 10, wherein:
the dielectric structure is a first dielectric structure;
the first source or drain body is between and in contact with the first dielectric structure and a second dielectric structure; and
the second source or drain body between and in contact with the first dielectric structure and a third dielectric structure.

12. The apparatus of claim 11, wherein:
the first nanoribbons extend through a first gate electrode;
the second nanoribbons extend through a second gate electrode; and
the dielectric structure is between the first and second gate electrodes.

13. The apparatus of claim 12, wherein the first nanoribbons have a first thickness greater than a second thickness of the second nanoribbons.

14. The apparatus of claim 13, wherein the apparatus is coupled to a host component, and the apparatus is coupled to a power supply through the host component.

15. A method, comprising:
forming a dielectric wall between first and second stacks of alternating first and second material layers over a substrate;
opening a first cavity on a first side of the dielectric wall, wherein first ends of the first and second material layers are exposed in the first cavity;
replacing the first ends of the second material layers with first cavity spacers;
growing a first source or drain body on first ends of the first material layers;
opening a second cavity on a second side of the dielectric wall, wherein second ends of the first and second material layers are exposed in the second cavity;
replacing the second ends of the first or second material layers with second cavity spacers; and
growing a second source or drain body on second ends of the second or first material layers.

16. The method of claim 15, wherein the forming the dielectric wall between the first and second stacks comprises etching through a dummy gate over the first and second stacks of the first and second material layers; and
further comprising:
opening third and fourth cavities on the first and second sides of the dielectric wall by removing first and second portions of the dummy gate;
removing the second material layers in the third cavity; and
removing the first material layers in the fourth cavity.

17. The method of claim 15, wherein:
forming the dielectric wall forms first and second dielectric walls; and
growing the first or second source or drain body grows the first or second source or drain body to contact the first and second dielectric walls to third and fourth sides of the first or second source or drain body.

18. The method of claim 15, further comprising recessing an upper surface of the second source or drain body to a first height lower than a second height of an upper surface of the first source or drain body.

19. The method of claim 15, further comprising thinning the first material layers to a first thickness less than a second thickness of the second material layers.

20. The method of claim 15, wherein:
the forming the dielectric wall between the first and second stacks of first and second material layers comprises:
opening a fifth cavity through a first dielectric material, wherein the fifth cavity extends substantially parallel to the first and second stacks of first and second material layers and through a dummy gate extending in a direction substantially orthogonal to the first and second stacks of first and second material layers; and
depositing a second dielectric material in the fifth cavity;
opening the first cavity on the first side of the dielectric wall opens a first pair of first cavities on the first side of the dielectric wall, the first stack of first and second material layers between the first cavities;
opening the second cavity on the second side of the dielectric wall opens a second pair of second cavities on the second side of the dielectric wall, the second stack of first and second material layers between the second cavities;
growing the first source or drain body grows a first pair of first source or drain bodies in the first cavities; and
growing the second source or drain body grows a second pair of second source or drain bodies in the second cavities.
